(19) United States
(12) Patent Application Publication
(10) Pub. No.: US 2009/0224354 A1
(43) Pub. Date: Sep. 10, 2009

(54) JUNCTION BARRIER SCHOTTKY DIODE WITH SUBMICRON CHANNELS

(75) Inventors: Andrei Konstantinov, Sollentuna (SE); Christopher Harris, Solna (SE); Jan-Olov Svederg, Jarfalla (SE)

Correspondence Address: VOLENTINE & WHITT PLLC, ONE FREEDOM SQUARE, 11951 FREEDOM DRIVE SUITE 1260, RESTON, VA, 20190, US

(73) Assignee: CREE, INC., Durham, NC (US)

(21) Appl. No.: 12/042,614

(22) Filed: Mar. 5, 2008

(51) Int. Cl. H01L 29/872; H01L 21/00

(52) U.S. Cl. 257/475; 438/328; 257/E29.338; 257/E21.359

(57) ABSTRACT

A junction barrier Schottky diode is provided as having submicron channel width between implant regions by way of a process including the use of spacer technology. On-state resistance is lowered by providing the implant regions in a channel layer having increased dopant concentration.

### STATEMENT OF GOVERNMENT INTEREST

The present invention was developed with Government support under contract number FA8650-04-2-2410 awarded by the U.S. Air Force. The Government has certain rights in this invention.

### BACKGROUND OF THE INVENTION

1. Field of the Invention

The present invention relates to junction barrier Schottky diodes having submicron channels, and a method of making junction barrier Schottky diodes.

2. Description of the Background Art

Silicon carbide Schottky rectifiers or diodes are a preferred technology for low-loss, high switching speed systems due to the high breakdown field of silicon carbide. There is however a tradeoff in the design of silicon carbide Schottky diodes between leakage of the low-barrier Schottky metal under high field conditions and forward voltage drop of high-barrier metals. This tradeoff can result in significant loss of performance. Junction barrier Schottky (JBS) diodes provide an efficient solution. However, optimum JBS implementation in silicon carbide requires a process with small critical dimensions. Such a process may result in low yield and unacceptably high process cost.

In conventional JBS implementation, implanted regions are disposed in the upper surface of the structure to pinch off or shield the high electric field from the Schottky metal. This process however requires implanting regions in silicon carbide with narrow regions there between. In the optimum case, such implantation would require high resolution lithography not normally used in high power device manufacture. Moreover, the narrow dimensions between such narrow implanted regions contribute to increased on-state resistance of the device. As a result, existing commercial JBS design uses larger p-regions with larger spacings there between.

Accordingly, there is a need to provide a JBS structure, and corresponding method of making such a JBS structure, whereby the JBS structure has submicron dimensions between implanted regions to effectively shield the Schottky barrier from high field regions and minimize reverse leakage, without increasing on-state resistance of the device.

### SUMMARY OF THE INVENTION

In accordance with a first embodiment, the method of manufacturing a junction barrier Schottky diode includes in combination epitaxially growing a drift layer on a first surface of a substrate, and a channel layer on the drift layer, the drift layer and the channel layer having a first conductivity type, and a dopant concentration of the channel layer is at least twice a dopant concentration of the drift layer; forming a first mask on the channel layer, the first mask having openings therethrough that expose a surface of the channel layer; depositing a first layer conformally on the first mask and the exposed surface of the channel layer; etching the first layer to expose the surface of the channel layer and so that portions of the first layer remain within the openings as spacers on sidewalls of the first mask; removing the first mask; implanting an impurity into the exposed surface of the channel layer using the spacers as a mask after said removing the first mask, to form implant regions having a second conductivity type opposite the first conductivity type; removing the spacers; depositing a first metal on a second surface of the substrate that is opposite the first surface; and depositing a second metal over the implant regions and the channel layer between the implant regions.

In accordance with another embodiment, a junction barrier Schottky diode includes in combination a drift layer on a first surface of a substrate; a channel layer on the drift layer, the drift layer and the channel layer are silicon carbide and have a first conductivity type, a dopant concentration of the channel layer is at least twice a dopant concentration of the drift layer; implant regions extending from a surface of the channel layer into the channel layer, the implant regions have a second conductivity type opposite the first conductivity type and are disposed in a grid-like pattern with a distance therebetween in a range of about 0.5 μm to 0.7 μm; a first metal on a second surface of the substrate that is opposite the first surface; and a second metal over the implant regions and the channel layer between the implant regions.

### BRIEF DESCRIPTION OF THE DRAWINGS

The above and other objects and features of the present invention will become apparent from the following description of the preferred embodiments made in connection with the accompanying drawings, in which:

FIG. 1 illustrates a cross-section of a junction barrier Schottky diode of an embodiment of the present invention;

FIG. 2 illustrates a cross-section of the structure after formation of a drift layer and a channel layer on a substrate;

FIG. 3 illustrates a cross-section after patterning of a mask layer;

FIG. 3A illustrates a top plan view of the mask layer;

FIG. 4 illustrates a cross-section of the structure after formation of a conformal layer on the patterned mask and on the exposed surface of the structure;

FIG. 5 illustrates a cross-section of the structure after etching to remove portions of the conformal layer to form spacers;

FIG. 6 illustrates a cross-section of the structure after removal of the mask pattern;

FIG. 7 illustrates a cross-section of the structure after formation of implant regions using the spacers as a mask;

FIG. 8 illustrates a cross-section of the structure after removal of the spacers;

FIG. 9 illustrates a cross-section of the structure after formation of a back side contact;

FIG. 10 illustrates characteristics of a junction barrier Schottky diode of FIG. 1 as a function of channel width between implant regions; and

FIG. 11 illustrates a cross-section of a junction barrier Schottky diode of a further embodiment having larger implant regions and thicker contacts.

### DETAILED DESCRIPTION OF THE PREFERRED EMBODIMENTS

The present invention will now be described more fully hereinafter with reference to the accompanying drawings, in which preferred embodiments of the invention are shown. This invention may however be embodied in many different forms and should not be construed as limited to the embodiments set forth herein. Rather, the embodiments as described are provided so that this disclosure will be thorough and complete, and will fully convey the concept of the invention to those skilled in the art. In the drawings, the shape and thickness of the elements and layers may be exaggerated for clarity, and are not necessarily drawn to scale. Also, like reference numbers are used to refer to like elements throughout the application. Description of well known methods and materials may be omitted.

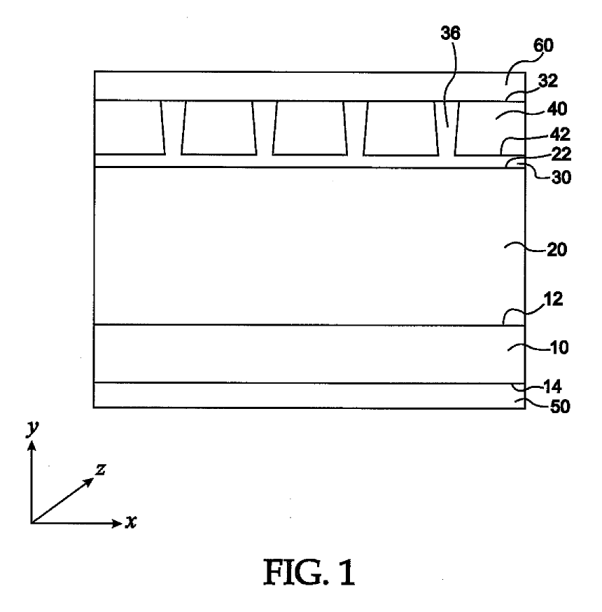

FIG. 1 is a cross-sectional view of a junction barrier Schottky (JBS) diode of an embodiment of the present application. As shown in FIG. 1, substrate 10 includes a first main or upper surface 12 and a second main or bottom surface 14 opposite first main surface 12. First and second main surfaces 12 and 14 may be characterized as front and back sides of substrate 10, whereby devices are disposed on or over first main surface 12. In this embodiment as described, substrate 10 is silicon carbide (SiC) having n-type conductivity, a thickness of about 300 to 500 μm, or about 400 μm, and a dopant concentration of at least about 5×10¹⁸ cm⁻³. Substrate 10 however should not necessarily be limited as silicon carbide, or as having n-type conductivity, but may be other materials such as silicon or GaN. Moreover, substrate 10 should not necessarily be limited as a single layer of silicon carbide or other substrate material, but may in general be a growth substrate with other intermediate epitaxial layers grown thereon.

As further shown in FIG. 1, an n-type conductivity drift layer 20 is disposed on or over first main surface 12 of substrate 10, and n-type conductivity channel layer 30 is disposed on or over upper surface 22 of drift layer 20. Drift layer 20 and channel layer 30 may be epitaxially grown layers of silicon carbide. Drift layer 20 has a dopant concentration not greater than 1×10¹⁶ cm⁻³. Channel layer 30 has a dopant concentration of at least 2×10¹⁶ cm⁻³. Drift layer 20 may have a thickness in a range of about 10 microns, and channel layer 30 may have a thickness in a range of about 1 micron. It should however be understood that the above noted thicknesses are merely exemplary, and that thickness of the layers may be appropriately selected to provide desired device characteristics. Also, in this embodiment, drift layer 20 and channel layer 30 are 4H crystal type layers of silicon carbide, whereby the top faces of each layer are the Si-face. In the alternative, drift layer 20 and channel layer 30 may be silicon or other semiconductor layers such as GaN.

As also shown in FIG. 1, a plurality of p-type conductivity implant regions 40 are disposed as extending into channel layer 30 from an upper or main surface 32 of channel layer 30, so that bottoms 42 of implant regions 40 are within channel layer 30. That is, portions of channel layer 30 remain disposed between bottoms 42 of implant regions 40 and upper surface 22 of drift layer 20. Implant regions 40 may have a depth in the vertical or y-direction of about 0.3 μm to 0.4 μm, and in this case consist of aluminum impurities. Implant regions 40 are separated from each other by channel regions 36 of channel layer 30. Channel regions 36 have a width in the horizontal or x-direction in a range of about 0.4 μm to 0.7 μm. The device further includes back side metallization or contact 50 disposed on second or lower surface 14 of substrate 10. Contact 50 may be nickel, titanium, titanium tungsten or aluminum, for example. The device as completed also includes front side metallization or contact 60 on upper surface 32 of channel layer 30. Contact 60 is a Schottky metal such as titanium, tungsten, platinum or nickel, and is disposed over channel regions 36 and implant regions 40.

A method of making the junction barrier Schottky (JBS) diode will now be described with respect to FIGS. 1-9. It should be understood that this description will be presented with reference to cross-sectionals of the device. Moreover, this description follows wherein substrate 10, drift layer 20 and channel layer 30 are n-type conductivity silicon carbide, and implant regions 40 have p-type conductivity. However, one of ordinary skill should understand that the above noted layers may be other materials such as silicon noted previously, and that conductivity may be reversed. The description that follows thus should not be construed as limiting.

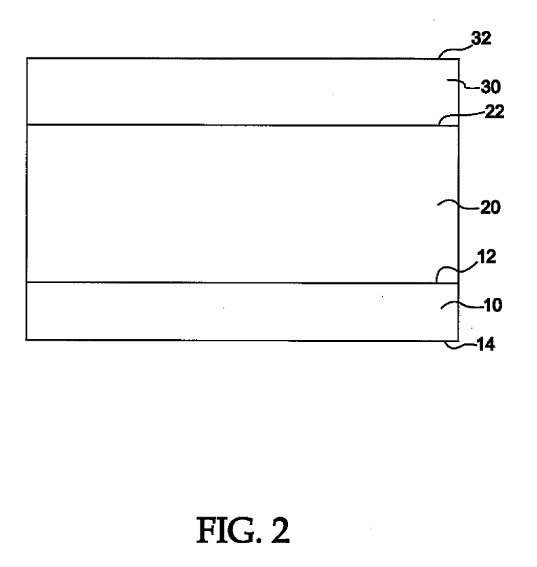

With reference to FIG. 2, silicon carbide drift layer 20 having n-type conductivity is first epitaxially grown on front surface 12 of substrate 10. Substrate 10 may have a thickness in a range of about 200 to 500 μm, and a dopant concentration at least greater than about 5×10¹⁸ cm⁻³. Drift layer 20 may have a thickness in a range of about 10 microns, and a dopant concentration not greater than about 1×10¹⁶ cm⁻³. Drift layer 20 may be epitaxially grown using well-known techniques such as Metal Organic Chemical Vapor Deposition (MOCVD). Nitrogen or phosphorous may be used as n-type dopants. Thereafter, silicon carbide channel layer 30 having n-type conductivity is epitaxially grown on upper surface 22 of drift layer 20. Channel layer 30 may have a thickness in a range of about 1 micron, and a dopant concentration of at least about 2×10¹⁶ cm⁻³. Although specific dopant concentrations of drift layer 20 and channel layer 30 are not identified, the dopant concentration of channel layer 30 should be at least 2 to 3 times greater than the dopant concentration of drift layer 20. For instance, if the dopant concentration of drift layer 20 is 2×10¹⁶ cm⁻³, the dopant concentration of channel layer 30 should be about 1×10¹⁷ cm⁻³. As a further example, if the dopant concentration of drift layer 20 is 2×10¹⁵ cm⁻³, the dopant concentration of channel layer should be about 1×10¹⁶ cm⁻³.

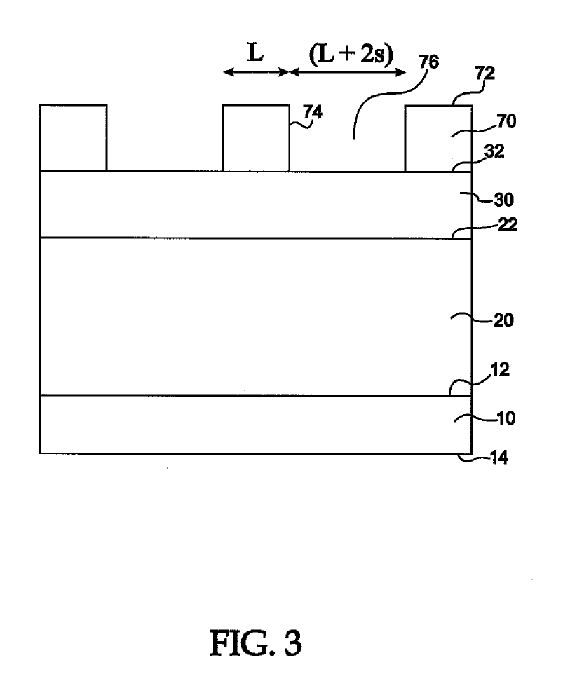

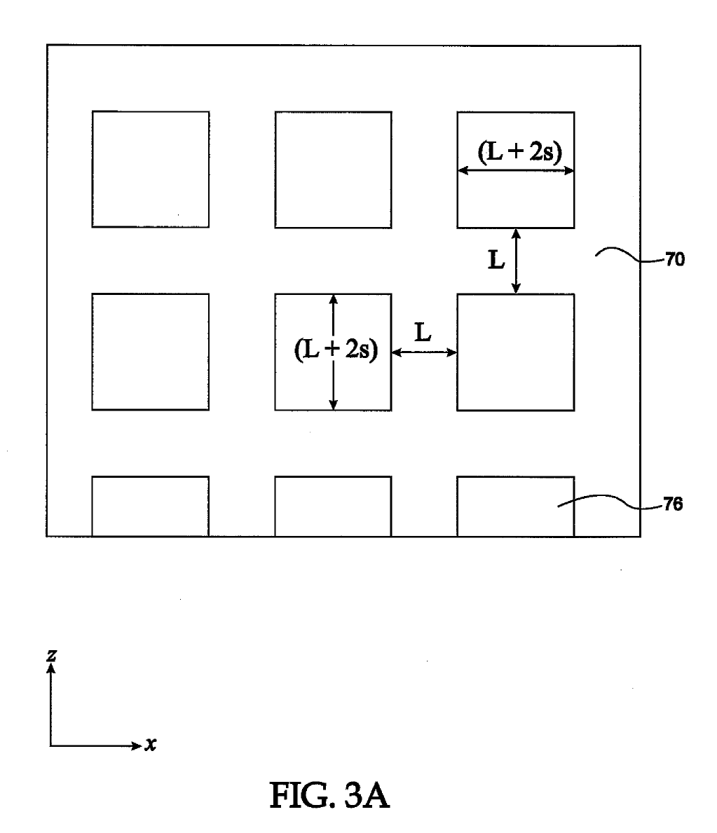

As described with respect to FIG. 3, an oxide layer such as silicon oxide having a thickness of about 1 μm is subsequently formed on an entirety of upper surface 22 of channel layer 30 of the structure shown in FIG. 2, by Plasma Enhanced Chemical Vapor Deposition (PECVD). The deposited oxide layer is then patterned using standard photolithographic techniques as would be understood by one of ordinary skill. That is, a photoresist layer is laid down on the oxide layer, the photoresist is developed, and a reactive ion etching (RIE) is carried out to remove the corresponding portions of the oxide layer. Oxide mask 70 is thus formed as having openings or windows 76 therethrough, whereby openings 76 expose portions of upper surface 32 of channel layer 30. The sidewalls of openings 76 are indicated by reference numeral 74.

In general, oxide mask 70 is formed in a grid-like design as shown in FIG. 3A, with openings 76 having length in the horizontal or x-direction and/or in the z-direction indicated as (L+2S). S represents spacer width which will become apparent as subsequently described, and L is the width of the grid sections of oxide mask 70 between adjacent openings 76. L is in a range of about 1.0 to 3.0 μm. Although mask 70 is described as silicon oxide, mask 70 may in the alternative be other materials such as polycrystalline silicon.

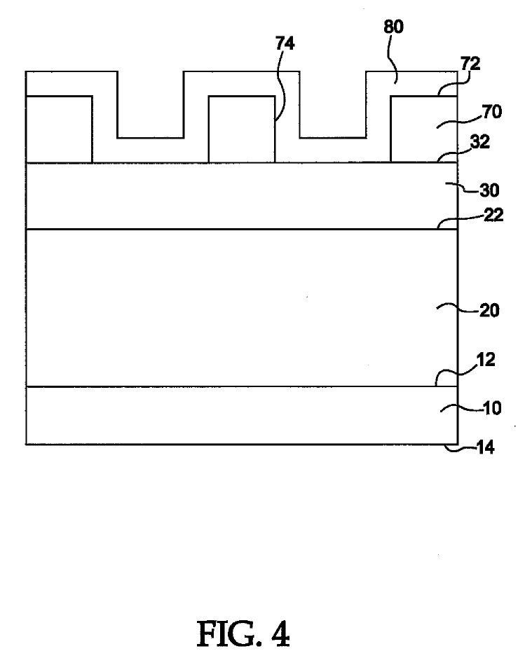

As described with respect to FIG. 4, a conformal layer 80 such as silicon nitride is deposited on oxide mask 72 shown in FIG. 3 by PECVD, and on upper surface 32 of channel layer 30 within openings 76 and on sidewalls 74 of oxide mask 70. Conformal layer 80 is deposited so as to have a thickness S, which is equivalent to spacer width as noted previously. That is, the thickness of conformal layer 80 defines spacer width S. For example only and not to be construed as limiting, conformal layer 80 may have a thickness in a range of about 0.5 microns. However, the thickness of conformal layer 80 (and consequently spacer width S) can be selected to provide desired device characteristics. Moreover, in the case that conformal layer 80 is a silicon nitride layer, conformal layer 80 may be deposited as a low stress silicon nitride layer by well-known low-stress techniques such as multi-frequency plasma deposition, to prevent cracking of conformal layer 80 during subsequent etching. Also, conformal layer 80 should not necessarily be limited as a silicon nitride layer, but in the alternative may be layers such as polycrystalline silicon (provided that polysilicon has not been used in the original mask).

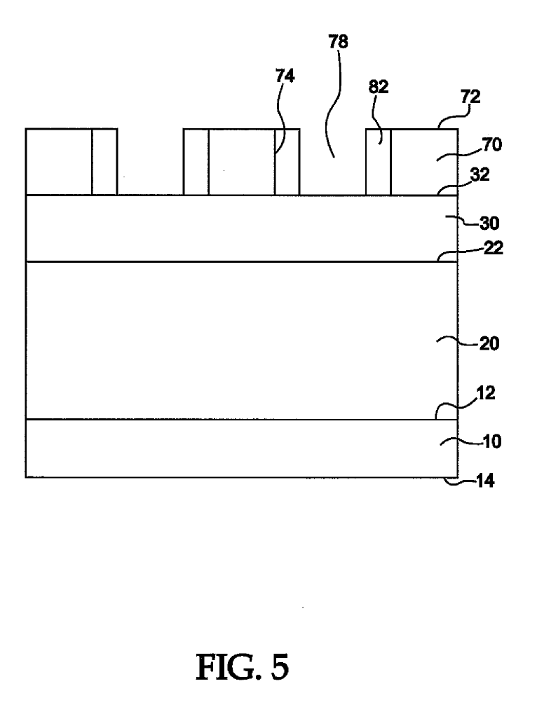

As described with respect to FIG. 5, reactive ion etching (RI E) is then carried out on the structure as shown in FIG. 4. This anisotropic etch removes conformal layer 80 from upper surface 72 of oxide mask 70 and from within central areas of the openings shown in FIG. 3 Portions of conformal layer 80 remain as spacers 82 on sidewalls 74 of oxide mask 70 over upper surface 32 of channel layer 30 at the periphery of openings 78, so that upper surface 32 of channel layer 30 is exposed at the central areas of openings 78 between spacers 82, as shown in FIG. 5.

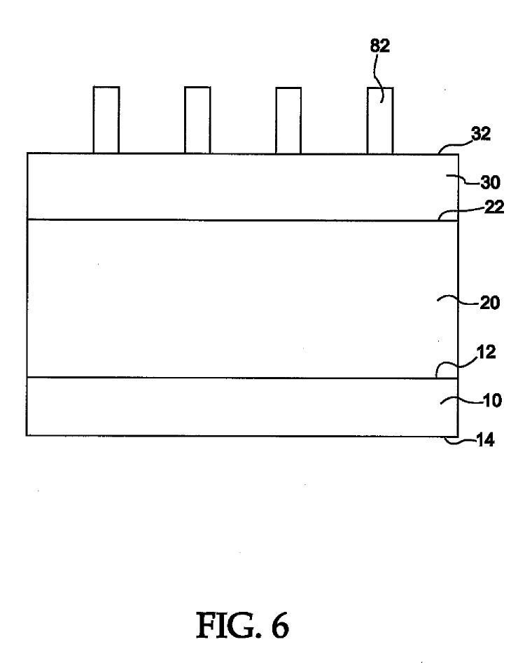

As described with respect to FIG. 6, a wet chemical etch using hydrofluoric acid for example is carried out on the structure shown in FIG. 5, to remove oxide layer 70. As a result, only silicon nitride spacers 82 substantially remain on upper surface 32 of channel layer 30, whereby spacers 82 may also be referred to hereinafter as pillars 82. If conformal layer 80 is a material layer other than silicon nitride, a corresponding chemical that realizes high etch selectivity between the conformal layer and channel layer 30 would be selected, as would be understood by one of ordinary skill.

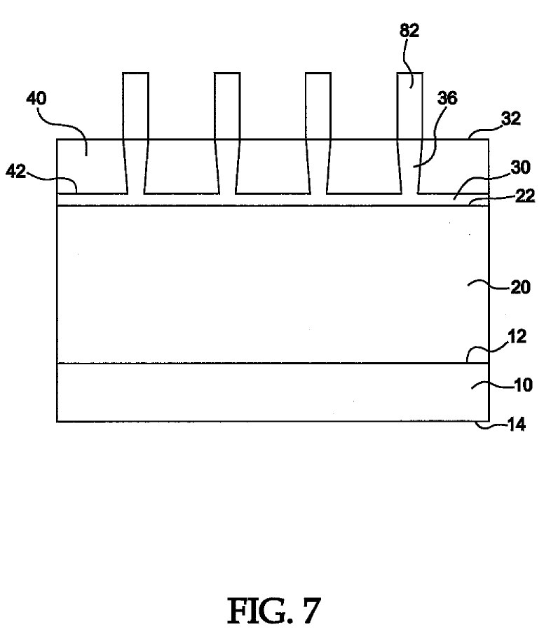

As described with respect to FIG. 7, ion implantation is subsequently carried out using pillars 82 as a mask, to form implant regions 40 of p-type conductivity. In the case that channel layer 30 and drift layer 20 are n-type conductivity silicon carbide, aluminum impurities may be implanted rather than boron, because of the extensive diffusion of boron. Implant regions 40 extend in a vertical or y-direction from upper surface 32 of channel layer 30 into channel layer 30 and have a depth of about 0.3 μm to 0.4 μm, whereby bottoms 42 of implant regions 40 are within channel layer 30. Implant regions 40 are separated or isolated away from each other in the horizontal or x-direction and/or in the z-direction by channel regions 36.

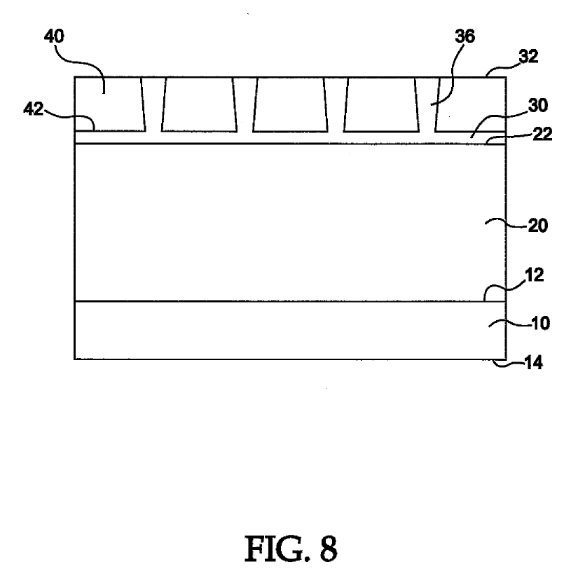

As described with respect to FIG. 8, after formation of implant regions 40, a wet chemical etch is carried out on the structure shown in FIG. 7 using hydrofluoric acid for example, to remove pillars 82. Thereafter, a high-temperature activation may be carried out at a temperature greater than at least 1600° C. for about 5 minutes. A graphite layer may be deposited on upper surface 32 of channel layer 30 and implant regions 40 as a capping layer prior to the high-temperature activation. For example, a resist layer may be deposited on upper surface 32 by spin coating, and the resist may then be baked, so as to form a black graphite coating on upper surface 32 that is able to withstand the very high temperatures of activation.

Also, the upper surface 32 of the structure shown in FIG. 8 may be processed after the high temperature activation, to increase the roughness thereof. To improve the quality of upper surface 32 before formation of Schottky metal thereon, for example, a very thin layer of upper surface 32 about 50 nm thick may be removed by etching. In the alternative, upper surface 32 may be oxidized, and the oxidation layer may be subsequently etched away. These processes help to eliminate or reduce defects between channel layer 32/implant regions 40 and the Schottky metal contact subsequently formed thereon, to reduce leakage current and thus improve the voltage blocking capability of the JBS diode.

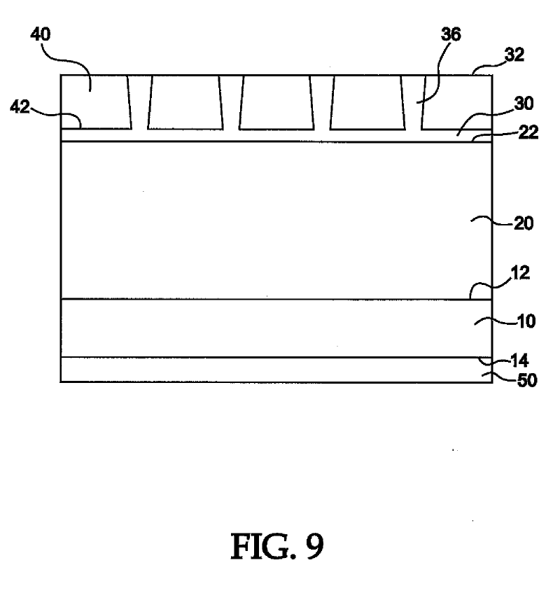

As described with respect to FIG. 9, a back side metallization is carried out to deposit contact 50 on second surface 14 of substrate 10 using well known deposition techniques. Metals such as nickel, titanium, titanium tungsten or aluminum, or various combinations may be used as contact 50. Contact 50 may have a thickness of about 100 nm. After deposition, a thermal anneal is subsequently carried out at a temperature of about 950° C. for about 5 minutes.

As further described with respect to FIG. 1, a front side metallization is then carried out after thermal annealing of contact 50 as described with respect to FIG. 9, to deposit contact 60 on upper surface 32 of contact layer 30, or more particularly on channel regions 36 and implant regions 40. A Schottky metal such as titanium, tungsten, platinum or nickel may be deposited using well known deposition techniques, to complete fabrication of the JBS diode.

As may be understood in view of FIG. 1, implant regions 40 are separated from each other by submicron channel regions 36, which have a length in a range of about 0.4 μm to 0.7 μm in the horizontal or x-direction and/or the z-direction. The submicron dimensions of vertical channel regions 36 are thus defined by spacers 82 rather than by a photolithographical process, so that a lithography fault tolerant design which is suitable for low-cost fabrication of silicon-carbide JBS diodes unattainable using standard micron size lithography can thus be achieved. Lithography process faults that may result in excessively wide channels prone to high leakage under high field conditions can be avoided. The JBS diode of FIG. 1 thus enables improved shielding of the surface of the structure.

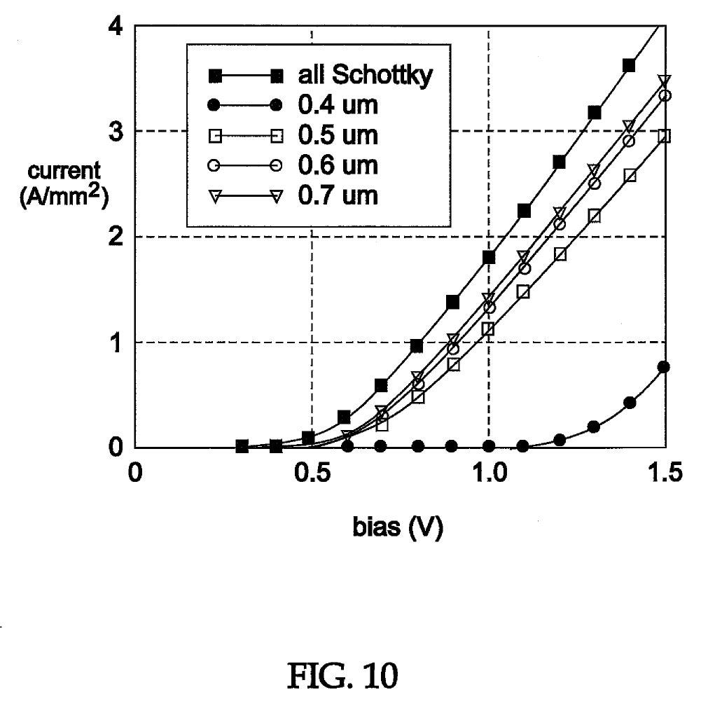

FIG. 10 illustrates simulated characteristics of a JBS diode of an embodiment of the present invention as described above with respect to FIG. 1, whereby channel current (A/mm²) is shown as a function of bias voltage (V) for various different channel region lengths along the horizontal or x-direction, for a channel dopant concentration of 1×10¹⁷ cm⁻³. The curve indicated by darkly shaded circles represents a channel width of 0.4 μm, the curve indicated by open squares represents a channel width of 0.5 μm, the curve represented by open circles represents a channel width of 0.6 μm, the curve represented by open triangles represents a channel width of 0.7 μm, and the curve represented by darkly shaded squares represents a Schottky diode structure without p-type implant regions 40 of the present invention.

As may be understood in view of FIG. 10, if the distance (channel width) between implant regions 40 is 0.4 μm, channel current is remarkably reduced due to narrowing of the channel. Channel width in the range of about 0.5 μm to 0.7 μm enables a channel current that begins to approximate current that would be realized by a Schottky diode without p-type implant regions. However, a tradeoff exists because as channel width increases, electric field strength at the Schottky junction increases and shielding of the Schottky junction is thus reduced. Also, although channel current is cut at a channel width of 0.4 μm as shown, this may be compensated for by increasing dopant concentration of channel region 36 to be greater than 1×10¹⁷ cm⁻³.

As described previously, the dopant concentration of channel layer 30 is 2 to 3 times greater than the dopant concentration of drift layer 20. The JBS diode as shown in FIG. 1 may thus be characterized as having a dopant profile that is stepped in the vertical or y-direction. The relatively higher dopant concentration of channel layer 30 compensates for high-on state resistance within narrow submicron channel regions 36. Channel layer 30 may also be provided as having a dopant profile that is graded in the vertical or y-direction. In this case, dopant concentration of channel layer 30 increases from a low-level near upper surface 22 of drift layer 20 that is optimized for near minimum drift layer resistance, to a high dopant concentration in (vertical) channel regions 36. For example, dopant concentration of the order of magnitude of about 10¹⁷ cm⁻³ would help to maintain a non-depleted state of vertical channels 36 under zero bias p-n junction conditions. Moreover, intermediate dopant concentration within channel layer 30 near bottoms 42 of implant regions 40 would help to minimize spreading resistance between adjacent channel regions 36, as well as smooth out the dopant transient.

In a variation of the JBS diode described with respect to FIG. 1, implant regions 40 at peripheral regions of the device may be larger than implant regions 40 near a central region of the device. For instance, and as provided merely as an example not to be construed as limiting, implant regions 40 in FIG. 1 at peripheral regions of the JBS diode may have a length in the horizontal or x-direction of about 2 microns, and implant regions 40 in a central region of the JBS diode of FIG. 1 may have a length in the horizontal or x-direction of less than 1 micron.

Upon application of a forward bias of about 1.0 to 1.2 volts to the JBS diode shown in FIG. 1, current will begin to flow vertically between Schottky metal contact 60 and channel regions 36 down to drift layer 20, substrate 10 and contact 50. At bias voltage of about 1.0 to 1.2 volts, the p-n junctions between implant regions 40 and channel layer 30 do not conduct current. Under surge conditions when the forward voltage drop in the region of the p-n junctions increase to about 2.5 to 2.7 volts, current will begin to flow across the p-n junctions between implant regions 40 and channel layer 30. The bipolar conduction generated by turning on the P-N junctions lowers the resistance of the drift region, allowing a higher current to flow, thus providing a path for the surge current. Incidentally, implant regions 40 can be made larger by expanding the dimensions of openings 76 in peripheral regions of oxide mask 70 in the horizontal or x-direction and/or the z-direction.

The embodiment described with respect to FIG. 1 as having larger implant regions at peripheral regions of the device may also include additional metallization on the larger implant regions at the peripheral regions of the device, to improve current flow through the p-n junctions during a high current surge condition. In particular, as described previously with respect to FIG. 9, contact 50 is annealed to improve contact quality, so that the lowest possible resistance is realized between contact 50 and substrate 10. Schottky metal contact 60 is thereafter deposited on upper surface 32 of channel layer 30 on channel regions 36 and implant regions 40 without being subsequently annealed, so that the barrier between contact 60 and the semiconductor material at channel regions 36 is not damaged. However, since contact 60 is not annealed, less than ideal contact quality may exist between contact 60 and implant regions 40.

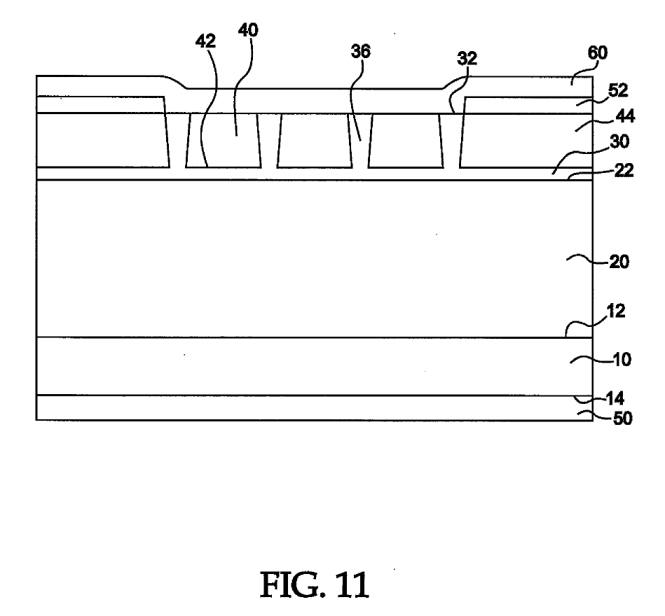

Accordingly, in a further embodiment as described with respect to FIG. 11, the metallization deposited as described with respect to FIG. 9 to form contact 50 on substrate 14 is also deposited on larger implant regions 44 at peripheral regions of the device, to form contacts 52 on larger implant regions 44. Masking may be used to prevent deposition of this metallization on remaining portions of upper surface 32. Contacts 52 are subsequently annealed along with contact 50 as described with respect to FIG. 9, so that improved contact quality and lower resistance is realized between contacts 52 and larger implant regions 44. Thereafter, Schottky contact 60 is deposited over contacts 52 and on the remaining exposed central region of the device after removal of any corresponding mask, whereby the barrier between Schottky metal contact 60 and channel regions 36 can be maintained without damage.

Although the present invention has been described in detail, the scope of the invention should not be limited by the corresponding description and figures. Also, the concepts described above should be applicable as well for the case where the conductivity types of substrate 10, drift layer 20 and channel layer 30 are reversed to be p-type, and the conductivity type of implant regions 40 is reversed to be n-type. Also, the structure has been described wherein drift layer 20 and channel layer 30 are 4H crystal type layers of silicon carbide. However, in alternative embodiments these layers may all be 6H crystal type layers of silicon carbide, or may all be 15R crystal type layers of silicon carbide. Also, the above noted layers may in the alternative have the C-faces as the top faces. These various changes and modifications of the embodiments, as would become apparent to one of ordinary skill, should be considered within the spirit and scope of the invention.

What is claimed is:

1. A method of manufacturing a junction barrier Schottky diode comprising:
epitaxially growing a drift layer on a first surface of a substrate, and a channel layer on the drift layer, the drift layer and the channel layer having a first conductivity type, and a dopant concentration of the channel layer is at least twice a dopant concentration of the drift layer;
forming a first mask on the channel layer, the first mask having openings therethrough that expose a surface of the channel layer;
depositing a first layer conformally on the first mask and the exposed surface of the channel layer;
etching the first layer to expose the surface of the channel layer and so that portions of the first layer remain within the openings as spacers on sidewalls of the first mask;
removing the first mask;
implanting an impurity into the exposed surface of the channel layer using the spacers as a mask after said removing the first mask, to form implant regions having a second conductivity type opposite the first conductivity type;
removing the spacers,
depositing a first metal on a second surface of the substrate that is opposite the first surface; and
depositing a second metal over the implant regions and the channel layer between the implant regions.

2. The method of manufacturing a junction barrier Schottky diode of claim 1, further comprising activating the implanted impurity with a high temperature anneal and subsequently removing surface defects, after said removing the spacers.

3. The method of manufacturing a junction barrier Schottky diode of claim 2, wherein said removing surface defects comprises etching.

4. The method of manufacturing a junction barrier Schottky diode of claim 2, wherein said removing surface defects comprises oxidation.

5. The method of manufacturing a junction barrier Schottky diode of claim 1, wherein a distance between the implant regions is in a range of about 0.5 μm to 0.7 μm.

6. The method of manufacturing a junction barrier Schottky diode of claim 1, wherein the dopant concentration of the drift layer is less than 1×10¹⁶ cm⁻³, and the dopant concentration of the channel layer is greater than 2×10¹⁶ cm⁻³.

7. The method of manufacturing a junction barrier Schottky diode of claim 1, wherein a length of the openings in periperhal areas of the first mask is greater than a length of the openings in a central area of the first mask, so that the implant regions are larger in peripheral areas of the junction barrier Schottky diode.

8. The method of manufacturing a junction barrier Schottky diode of claim 1, wherein said depositing a first metal further includes depositing the first metal directly on the implant regions, the method further comprising:
annealing the first metal,
said depositing a second metal occurs after said annealing and comprises depositing the second metal directly on the channel layer between the implants, and on the first metal deposited on the implant regions.

9. The method of manufacturing a junction barrier Schottky diode of claim 1, wherein the first layer is a silicon nitride layer.

10. The method of manufacturing a junction barrier Schottky diode of claim 1, wherein the first mask is an oxide mask.

11. The method of manufacturing a junction barrier Schottky diode of claim 1, wherein the first conductivity type is n-type conductivity and the second conductivity type is p-type conductivity.

12. The method of manufacturing a junction barrier Schottky diode of claim 1, wherein the drift layer and the channel layer are silicon carbide.

13. The method of manufacturing a junction barrier Schottky diode of claim 1, wherein the openings in the first mask are disposed in a grid-like pattern.

14. The method of manufacturing a junction barrier Schottky diode of claim 1, wherein the channel layer is epitaxially grown so that the dopant concentration is graded in a vertical direction.

15. A junction barrier Schottky diode comprising:
a drift layer on a first surface of a substrate;
a channel layer on the drift layer, the drift layer and the channel layer are silicon carbide and have a first conductivity type, a dopant concentration of the channel layer is at least twice a dopant concentration of the drift layer;
implant regions extending from a surface of the channel layer into the channel layer, the implant regions have a second conductivity type opposite the first conductivity type and are disposed in a grid-like pattern with a distance therebetween in a range of about 0.5 μm to 0.7 μm;
a first metal on a second surface of the substrate that is opposite the first surface; and
a second metal over the implant regions and the channel layer between the implant regions.

16. The junction barrier Schottky diode of claim 15, wherein the dopant concentration of the drift layer is less than 1×10¹⁶ cm⁻³, and the dopant concentration of the channel layer is greater than 2×10¹⁶ cm⁻³.

17. The junction barrier Schottky diode of claim 15, wherein the implant regions in peripheral areas of the grid-like pattern are larger than the implant regions in a central area of the grid-like pattern.

18. The junction barrier Schottky diode of claim 15, wherein the first metal is also directly on the implant regions, and the second metal is directly on the channel layer between the implant regions and is on the first metal that is directly on the implant regions.

19. The junction barrier Schottky diode of claim 15, wherein the first conductivity type is n-type conductivity and the second conductivity type is p-type conductivity.

20. The junction barrier Schottky diode of claim 15, wherein the dopant concentration of the channel layer is graded in a vertical direction.

21. A junction barrier Schottky diode comprising:
a drift layer on a substrate;
a channel layer on the drift layer, the channel layer and the drift layer are silicon carbide; and
implant regions extending from a surface of the channel layer into the channel layer, wherein the implant regions are separated from each other by a channel width less than about 1 μm.

22. The junction barrier Schottky diode of claim 21, wherein the channel width is less than about 0.7 μm.

23. The junction barrier Schottky diode of claim 21, wherein the channel width is in a range of about 0.5 μm to 0.7 μm.
